(19) United States
(12) Patent Application Publication
(10) Pub. No.: US 2022/0018790 A1
(43) Pub. Date: Jan. 20, 2022

(54) ABNORMALITY DETECTING METHOD AND ABNORMALITY DETECTING APPARATUS

(71) Applicant: Tokyo Electron Limited, Tokyo (JP)

(72) Inventor: Yuka NAKASATO, Yamanashi (JP)

(21) Appl. No.: 17/372,834

(22) Filed: Jul. 12, 2021

(30) Foreign Application Priority Data
Jul. 15, 2020 (JP) 2020-121138

(51) Int. Cl. G01N 21/95; G01N 21/88; G01N 21/84; H01L 21/66; G06N 20/00; G06T 7/00

(52) U.S. Cl. CPC G01N 21/9501; G01N 21/8851; G01N 21/8422; H01L 22/12; G01N 2021/8461; G06T 7/0004; G06T 2207/30148; G01N 2021/8861; G01N 2021/8887; G06N 20/00

(57) ABSTRACT

An abnormality detecting method includes: generating substrate information that represents a relationship between an in-plane position of a substrate processed in a semiconductor manufacturing apparatus and a film characteristic; and determining whether the film characteristic of the processed substrate is abnormal, based on the substrate information generated in the generating, and association information in which substrate information and abnormality factors are associated with each other.

### CROSS-REFERENCE TO RELATED APPLICATIONS

This application is based on and claims priority from Japanese Patent Application No. 2020-121138 filed on Jul. 15, 2020 with the Japan Patent Office, the disclosure of which is incorporated herein in its entirety by reference.

### TECHNICAL FIELD

The present disclosure relates to an abnormality detecting method and an abnormality detecting apparatus.

### BACKGROUND

A technique is known which generates defect distribution image data based on the position data of a defect on an inspected semiconductor wafer, and grasps the state of the occurrence of the defect on the semiconductor wafer based on the defect distribution image data (see, e.g., Japanese Patent Laid-Open Publication No. 11-045919).

### SUMMARY

According to an aspect of the present disclosure, an abnormality detecting method includes: generating substrate information that represents a relationship between an in-plane position of a substrate processed in a semiconductor manufacturing apparatus and a film characteristic; and determining whether the film characteristic of the processed substrate is abnormal, based on the substrate information generated in the generating, and association information in which substrate information and abnormality factors are associated with each other.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of an overall configuration of a system.

FIG. 2 is a view illustrating an example of a hardware configuration of a group management controller.

FIG. 3 is a view illustrating an example of a functional configuration of the group management controller.

FIG. 4 is a view illustrating an example of a wafer map and a database.

FIG. 5 is a view illustrating an example of a model generating process.

FIG. 6 is a view illustrating an example of a determining process.

FIG. 7 is a flowchart illustrating an example of an abnormality detecting method according to an embodiment.

FIG. 8 is a view illustrating another example of the functional configuration of the group management controller.

FIG. 9 is a view illustrating another example of the model generating process.

FIG. 10 is a view illustrating another example of the determining process.

### DETAILED DESCRIPTION

In the following detailed description, reference is made to the accompanying drawings which form a part hereof. The illustrative embodiments described in the detailed description, drawing, and claims are not meant to be limiting. Other embodiments may be utilized, and other changes may be made without departing from the spirit or scope of the subject matter presented here.

Hereinafter, non-limiting embodiments of the present disclosure will be described with reference to the accompanying drawings. In all of the drawings, the same or corresponding members or components will be denoted by the same or corresponding reference numerals, and overlapping descriptions thereof will be omitted.

[System]

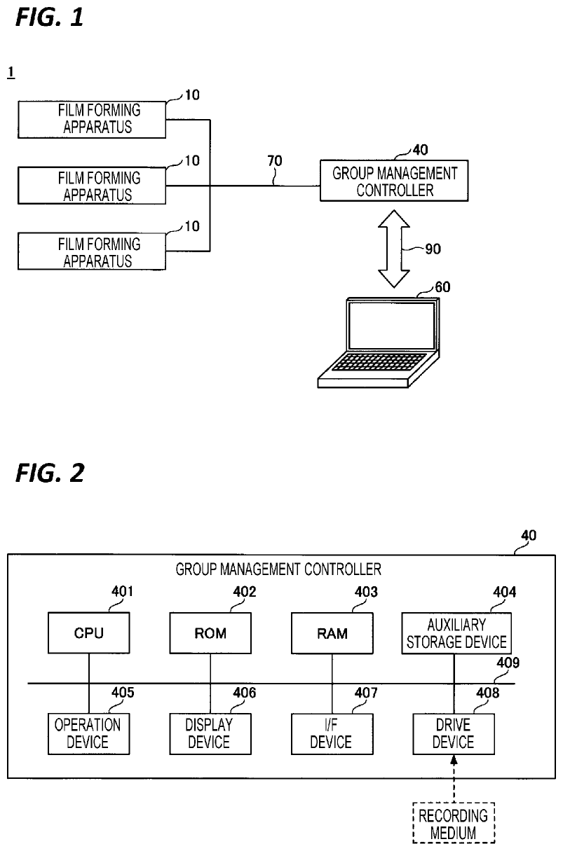

Referring to FIG. 1, an overall configuration of a system will be described. FIG. 1 is a view illustrating an example of the overall configuration of the system.

A system 1 includes three film forming apparatuses 10, a group management controller 40, and a terminal 60. Each film forming apparatus 10 is communicably connected to the group management controller 40 via a network 70. The group management controller 40 is communicably connected to the terminal 60 via a network 90. While FIG. 1 represents three film forming apparatuses 10, the number of film forming apparatuses may be two or less, or four or more.

[Film Forming Apparatus]

Each film forming apparatus 10 executes various semiconductor manufacturing processes. The semiconductor manufacturing processes include various processes for manufacturing a semiconductor device, such as, for example, a film forming process, an etching process, and a heating process.

The film forming apparatus 10 may be, for example, a cluster type apparatus in which a plurality of processing chambers is arranged around a transfer chamber, or an in-line type apparatus in which one processing chamber is disposed in one transfer chamber. Further, the film forming apparatus 10 may be, for example, any one of a single-wafer type apparatus, a semi-batch type apparatus, and a batch type apparatus. The single-wafer type apparatus is, for example, an apparatus that processes semiconductor wafers which are each an example of a substrate (hereinafter, simply referred to as a “wafer”), one by one in a processing chamber. The semi-batch type apparatus is, for example, an apparatus in which a plurality of wafers placed on a rotary table in a processing chamber is revolved by the rotary table, such that each wafer passes through a region where a raw material gas is supplied and a region where a reaction gas that reacts with the raw material gas is supplied, in an order, thereby forming a film on the surface of the wafer. The batch type apparatus is, for example, an apparatus in which a processing chamber accommodates a wafer boat that holds a plurality of wafers horizontally at predetermined intervals in the height direction, thereby processing the plurality of wafers at once.

The film forming apparatus 10 may be communicably connected to a host computer (not illustrated) via a network. The host computer may be connected to a device other than the semiconductor manufacturing apparatus 10 in a semiconductor factory, such as, for example, an inspection device for inspecting a semiconductor device manufactured by the semiconductor manufacturing apparatus 10 via a network. The inspection device includes, for example, a film thickness measuring device, an electrical characteristic measuring device, an optical characteristic measuring device, and a particle measuring device.

[Group Management Controller]

Referring to FIG. 2, a hardware configuration of the group management controller 40 will be described. FIG. 2 is a view illustrating an example of the hardware configuration of the group management controller 40.

The group management controller 40 includes a central processing unit (CPU) 401, a read only memory (ROM) 402, and a random access memory (RAM) 403. The CPU 401, the ROM 402, and the RAM 403 make up a so-called computer. The group management controller 40 further includes an auxiliary storage device 404, an operation device 405, a display device 406, an interface (I/F) device 407, and a drive device 408. The hardware components of the group management controller 40 are connected to each other via a bus 409.

The CPU 401 executes various programs installed in the auxiliary storage device 404.

The ROM 402 is a non-volatile memory, and functions as a main storage device. The ROM 402 stores various programs, information, and others which are necessary when the CPU 401 executes the various programs installed in the auxiliary storage device 404.

The RAM 403 is a volatile memory such as a dynamic random access memory (DRAM) or a static random access memory (SRAM), and functions as a main storage device. The RAM 403 provides a work area where programs are to be developed when the CPU 401 executes the various programs installed in the auxiliary storage device 404.

The auxiliary storage device 404 stores various programs, or information that represents the state of the film forming apparatus 10 when the CPU 401 executes the various programs.

The operation device 405 is an input device used when an operator inputs various instructions to the group management controller 40.

The display device 406 displays internal information of the group management controller 40.

The I/F device 407 is a connection device that is connected to the network 70 to communicate with the film forming apparatus 10.

The drive device 408 is a device that performs a writing and a reading with respect to a recording medium. The recording medium includes, for example, a CD-ROM, a flexible disk, a magneto-optical disk, a ROM, and a flash memory.

For example, the various programs installed in the auxiliary storage device 404 are installed in the manner that a distributed recording medium is inserted into the drive device 408, and various programs recorded in the recording medium are read by the drive device 408.

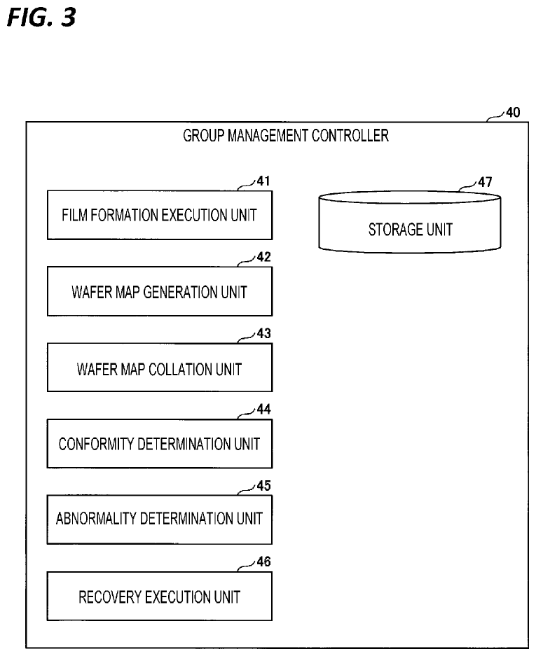

Referring to FIGS. 3 to 6, the functional configuration of the group management controller 40 will be described. FIG. 3 is a view illustrating an example of the functional configuration of the group management controller 40.

The group management controller 40 includes a film formation execution unit 41, a wafer map generation unit 42, a wafer map collation unit 43, a conformity determination unit 44, an abnormality determination unit 45, a recovery execution unit 46, and a storage unit 47.

The film formation execution unit 41 causes the film forming apparatus 10 to execute a film forming process under predetermined process conditions, so as to form a predetermined film on a wafer. The predetermined process conditions are predetermined by, for example, a process recipe. The predetermined film may be, for example, an insulating film, a metal film, or a semiconductor film.

The wafer map generation unit 42 generates a wafer map. The wafer map is information that represents a relationship between an in-plane position of the wafer and a film characteristic. Examples of the film characteristic include a film thickness, a film quality, and particles. For example, the wafer map generation unit 42 generates the wafer map, based on actual measurement values obtained by measuring the film characteristic of the predetermined film formed on the wafer when the film forming apparatus 10 executes the film forming process, using an inspection device. Further, for example, the wafer map generation unit 42 generates the wafer map, based on a predicted value of the film characteristic that is predicted by a simulation using the process conditions for the film forming process executed in the film forming apparatus 10.

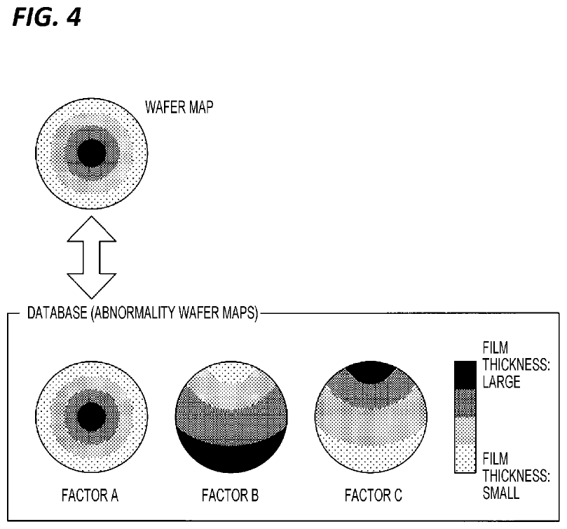

FIG. 4 is a view illustrating an example of a wafer map and a database. As illustrated in FIG. 4, the wafer map is a circular image that represents the shape of the wafer, and includes a wafer image in which the distribution of a film characteristic (e.g., a film thickness) in the plane of the wafer is represented in a color gradation. In the wafer map represented in FIG. 4, the distribution of the film thickness in the plane of the wafer is represented in a gradation that shifts from white to black as the film thickness increases. However, for example, the distribution of the film thickness in the plane of the wafer may be represented in a gradation that shifts from a long-wavelength color (e.g., red) to a short-wavelength color (e.g., green) as the film thickness increases, or may be represented by a gradation of other colors.

The wafer map collation unit 43 collates the wafer map generated by the wafer map generation unit 42 with the database stored in the storage unit 47. For example, as illustrated in FIG. 4, the database includes abnormality wafer maps in which wafer maps obtained from past abnormalities are classified by factors. For example, the wafer map collation unit 43 estimates an abnormality factor of the predetermined film formed on the wafer, based on the wafer map generated by the wafer map generation unit 42 and a trained model in which a machine learning has been performed using the database. Further, for example, the wafer map collation unit 43 may estimate an abnormality factor of the predetermined film formed on the wafer, based on the wafer map generated by the wafer map generation unit 42 and the abnormality wafer maps of the database, through a pattern matching.

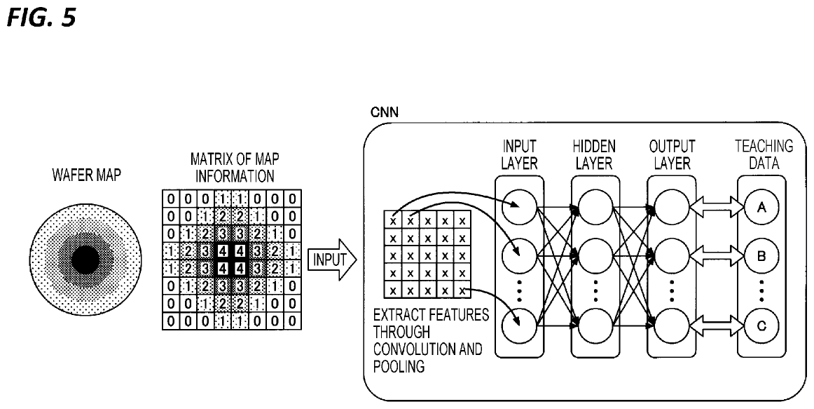

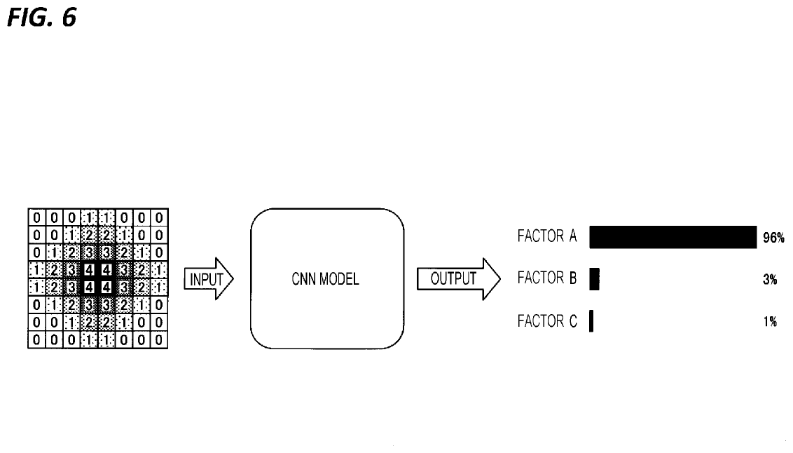

For example, as illustrated in FIG. 5, the trained model is configured as a neural network. In the present embodiment, the neural network is a so-called deep neural network which includes one or more hidden layers between an input layer and an output layer. In the neural network, a weighting parameter is defined which represents the connection strength of each of a plurality of neurons included in each hidden layer with the lower layer. The neural network is configured such that the sum of values obtained by multiplying each of input values from a plurality of neurons of the upper layer by a weighting parameter defined for each neuron of the upper layer is output to neurons of the lower layer through a threshold function. The wafer map collation unit 43 performs a machine learning, specifically, a deep learning on the neural network, so that the weighting parameter described above may be optimized. As a result, for example, as illustrated in FIG. 6, the wafer map generated by the wafer map generation unit 42 is input as an input signal to the neural network, and the neural network outputs a probability value for each abnormality factor as an output signal. In the example illustrated in FIG. 6, the neural network outputs a probability value of a factor A, a probability value of a factor B, and a probability value of a factor C. As a result, the wafer map collation unit 43 may estimate an abnormality factor of the predetermined film formed on the wafer, based on the probability value of each abnormality factor output by the neural network, that is, the probability value of the factor A, the probability value of the factor B, and the probability value of the factor C. The neural network is, for example, a convolutional neural network (CNN). The CNN is a neural network to which existing image processing techniques (convolution processing and pooling processing) are applied. Specifically, the CNN repeats a combination of the convolution processing and the pooling processing on the wafer map generated by the wafer map generation unit 42, thereby extracting feature amount data (feature map) with a size smaller than that of the wafer map. Then, a pixel value of each pixel of the extracted feature map is input to the neural network configured by a plurality of fully connected layers, and the output layer of the neural network outputs a probability value for each abnormality factor.

The conformity determination unit 44 determines whether the wafer map generated by the wafer map generation unit 42 conforms to the database, based on the result of the collation performed by the wafer map collation unit 43.

For example, the conformity determination unit 44 determines whether the wafer map generated by the wafer map generation unit 42 conforms to any of the plurality of wafer maps in the database, based on the probability value for each abnormality factor output by the neural network. Specifically, when any of the probability values for the abnormality factors output by the neural network is equal to or higher than a value specified in advance (specified value), the conformity determination unit 44 determines that the wafer map generated by the wafer map generation unit 42 conforms to the database. For example, as illustrated in FIG. 6, when the probability value of the factor A is 96%, the probability value of the factor B is 3%, the probability value of the factor C is 1%, and the specified value is 90%, the conformity determination unit 44 determines that the wafer map generated by the wafer map generation unit 42 conforms to the database. Meanwhile, when none of the probability values of the abnormality factors output by the neural network is equal to or higher than the specified value, the conformity determination unit 44 determines that the wafer map generated by the wafer map generation unit 42 does not conform to the database.

Further, for example, the conformity determination unit 44 may determine whether the wafer map generated by the wafer map generation unit 42 conforms to any one of the plurality of abnormality wafer maps in the database, based on a result of the pattern matching. Specifically, when any one of similarities between the wafer map generated by the wafer map generation unit 42 and the plurality of respective abnormality wafer maps in the database is equal to or higher than a value specified in advance (specified value), the conformity determination unit 44 determines that the wafer map conforms to the database. Meanwhile, when none of the similarities is equal to or higher than the specified value, the conformity determination unit 44 determines that the wafer map generated by the wafer map generation unit 42 does not conform to the database.

When the conformity determination unit 44 determines that the wafer map generated by the wafer map generation unit 42 does not conform to the database, the abnormality determination unit 45 determines that the result of the film forming process, that is, the film characteristic of the predetermined film is normal. Further, when the conformity determination unit 44 determines that the wafer map generated by the wafer map generation unit 42 conforms to the database, the abnormality determination unit 45 determines that the result of the film forming process, that is, the film characteristic of the predetermined film are abnormal. Further, when it is determined that the result of the film forming process is abnormal, the abnormality determination unit 45 estimates the factor of the abnormality. For example, the abnormality determination unit 45 estimates the factor of the abnormality based on the probability value for each abnormality factor output by the neural network. In the example of FIG. 6, the abnormality determination unit 45 estimates that the factor A with the probability value equal to or higher than the specified value is the factor of the abnormality. Further, for example, the abnormality determination unit 45 estimates that a factor in which the similarity obtained by the pattern matching is equal to or higher than the specified value is the factor of the abnormality.

The recovery execution unit 46 executes a predetermined abnormality recovering process for the factor of the abnormality that has been estimated by the abnormality determination unit 45. For example, based on the factor of the abnormality estimated by the abnormality determination unit 45 and association information in which abnormality factors and countermeasures are associated with each other, the recovery execution unit 46 executes an abnormality recovering process that corresponds to the factor of the abnormality estimated by the abnormality determination unit 45.

[Abnormality Detecting Method]

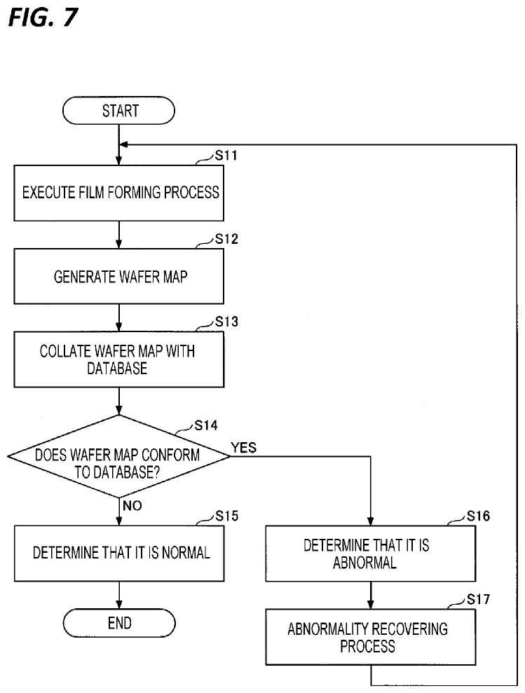

Referring to FIG. 7, descriptions will be made on an example of a method of detecting an abnormality of a substrate on which a predetermined film is formed in the film forming apparatus 10 (an abnormality detecting method). FIG. 7 is a flowchart illustrating an example of the abnormality detecting method according to the embodiment.

In step S11, the group management controller 40 causes the film forming apparatus 10 to execute the film forming process under predetermined process conditions, so as to form a predetermined film on the wafer. The predetermined process conditions are predetermined by, for example, a process recipe. The predetermined film may be, for example, an insulating film, a metal film, or a semiconductor film.

In step S12, the group management controller 40 generates a wafer map. The wafer map is information that represents the distribution of a film characteristic in the plane of the wafer. Examples of the film characteristic include a film thickness, a film quality, and particles. For example, the group management controller 40 generates the wafer map, based on actual measurement values obtained by measuring the film characteristic of the predetermined film formed on the wafer when the film forming apparatus 10 executes the film forming process, using an inspection device. Further, for example, the wafer map generation unit 40 generates the wafer map, based on a predicted value of the film characteristic that is predicted by a simulation using the process conditions for the film forming process executed in step S11.

In step S13, the group management controller 40 collates the wafer map generated in step S12 with the database. In the database, wafer maps obtained from past abnormalities are classified by factors. For example, the group management controller 40 estimates an abnormality factor of the predetermined film formed in step S11, based on the wafer map generated in step S12 and a trained model in which a machine learning has been performed using the database. Further, for example, the group management controller 40 may estimate an abnormality factor of the predetermined film formed in step S11, based on the wafer map generated in step S12 and the abnormality wafer maps in the database, through the pattern matching.

In step S14, the group management controller 40 determines whether the wafer map generated in step S12 conforms to the database, based on the result of the collation performed in step S13. For example, the group management controller 40 determines whether the wafer map generated in step S12 conforms to any one of the plurality of abnormality wafer maps in the database, based on the probability value for each abnormality factor output by the neural network. Further, for example, the group management controller 40 may determine whether the wafer map generated in step S12 conforms to any one of the plurality of abnormality wafer maps in the database, based on the result of the pattern matching. When it is determined in step S14 that the wafer map generated in step S12 does not conform to the database, the group management controller 40 causes the process to proceed to step S15. Meanwhile, when it is determined in step S14 that the wafer map generated in step S12 conforms to the database, the group management controller 40 causes the process to proceed to step S16.

In step S15, the group management controller 40 determines that the film forming apparatus 10 is normal, and ends the process.

In step S16, the group management controller 40 determines that the result of the film forming process, that is, the film characteristic of the predetermined film is abnormal, estimates the factor of the abnormality, and causes the process to proceed to step S17. For example, the group management controller 40 estimates the factor of the abnormality based on the probability value for each abnormality factor output by the neural network. Further, for example, the group management controller 40 estimates that a factor in which the similarity obtained by the pattern matching is equal to or higher than the specified value is the factor of the abnormality.

In step S17, the group management controller 40 executes a predetermined abnormality recovering process for the factor of the abnormality estimated in step S16, and then, returns the process to step S11. For example, based on the factor of the abnormality estimated in step S16 and the association information in which abnormality factors and countermeasures are associated with each other, the group management controller 40 executes the abnormality recovering process that corresponds to the factor of the abnormality estimated in step S16.

As described above, according to the abnormality detecting method of the embodiment, the wafer map generated after the film forming process is collated with the database. When the wafer map does not conform to the database, it is determined to be normal, and when the wafer map conforms to the database, it is determined to be abnormal. As a result, an apparatus manager or the like may easily find out whether the result of the film formation is normal or abnormal.

Further, according to the abnormality detecting method of the embodiment above, when the wafer map generated after the film forming process conforms to the database, the factor of the abnormality is estimated based on the wafer map and the database. As a result, the factor of the abnormality in product quality may be automatically estimated. Thus, the apparatus manager or the like does not need to conduct experiments and inspections for finding out the cause of an abnormality each time the abnormality occurs, and human costs and time costs may be reduced. Meanwhile, since there may exist various causes for the abnormality of product quality in the film forming apparatus, high human costs and time costs are required when the apparatus manager or the like conducts experiments and inspections for finding out the cause of an abnormality each time the abnormality occurs.

Meanwhile, in the abnormality detecting method of the embodiment above, descriptions are made on a case where when the wafer map generated after the film forming process conforms to the database, it is determined that the film forming apparatus 10 is abnormal, and the abnormality recovering process that corresponds to the factor of the abnormality is executed. However, the abnormality recovering process may not be executed. For example, when the abnormality recovering process is not executed, the non-execution may be notified to the apparatus manager or the like, and then, the process may be ended. While the method of making the notification to the apparatus manager or the like is not specifically limited, for example, the display device 406 of the group management controller 40 or the apparatus controller 12 of the film forming apparatus 10 may display a countermeasure that corresponds to the factor of the abnormality.

Further, in the abnormality detecting method of the embodiment above, descriptions are made on a case where the wafer map is used. However, the present disclosure is not limited to using the wafer map. For example, a wafer table may be used, instead of the wafer map.

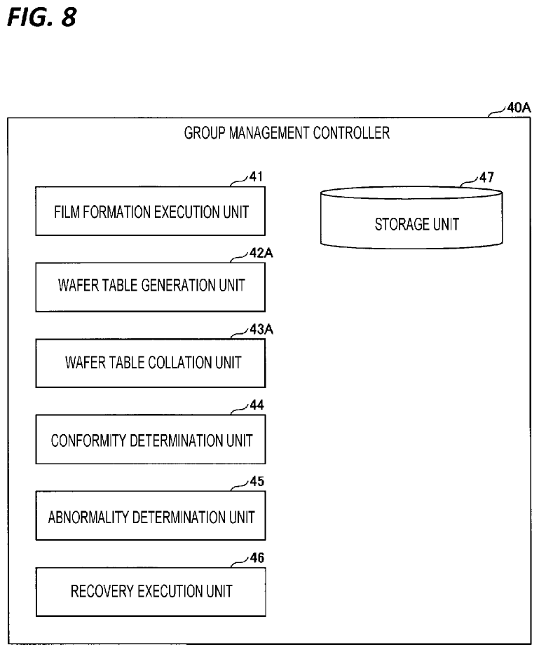

FIG. 8 is a view illustrating another example of the functional configuration of the group management controller. As illustrated in FIG. 8, a group management controller 40A includes a wafer table generation unit 42A, instead of the wafer map generation unit 42, and includes a wafer table collation unit 43A, instead of the wafer map collation unit 43, as the components of the functional configuration.

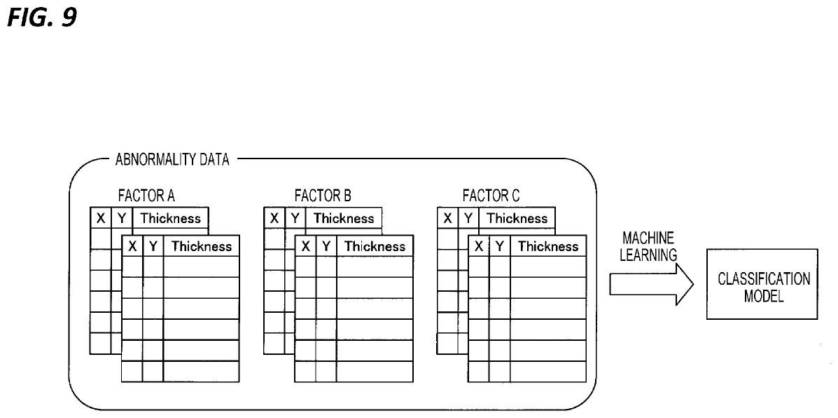

The wafer table generation unit 42A generates a wafer table. The wafer table is information that represents a relationship between an in-plane position of the wafer and a film characteristic. For example, as illustrated in FIG. 9, the wafer table is information in which position coordinates (X, Y) in the plane of the wafer and a film thickness (Thickness) are associated with each other. Examples of the film characteristic include a film thickness, a film quality, and particles. For example, the wafer table generation unit 42A generates a wafer table, based on actual measurement values obtained by measuring the film characteristic of the predetermined film formed on the wafer when the film forming apparatus 10 executes the film forming process, using an inspection device. Further, for example, the wafer table generation unit 42A generates the wafer table, based on a predicted value of the film characteristic that is predicted by a simulation using the process conditions for the film forming process executed in the film forming apparatus 10.

The wafer table collation unit 43A collates the wafer table generated by the wafer table generation unit 42A with the database stored in the storage unit 47. The database includes abnormality wafer tables in which wafer tables obtained from past abnormalities are classified by factors. For example, the wafer table collation unit 43A estimates an abnormality factor of the predetermined film formed on the wafer, based on the wafer table generated by the wafer table generation unit 42A and a trained model (classification model) in which a machine learning has been performed by using the database. Further, for example, the wafer table collation unit 43A may estimate the abnormal factor of the predetermined film formed on the wafer, based on the wafer table generated by the wafer table generation unit 42A and the abnormality wafer tables of the database, through the pattern matching.

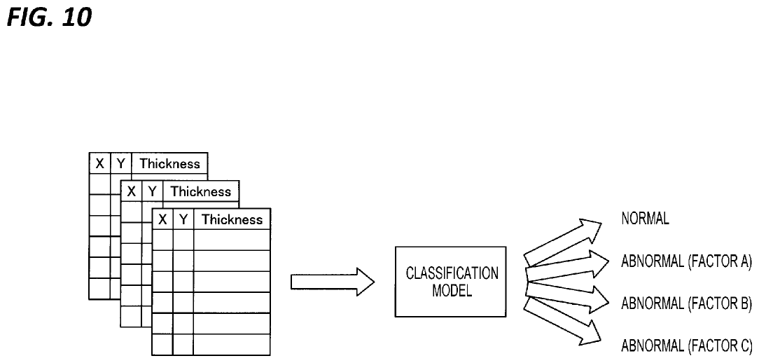

The trained model is configured as, for example, a neural network. In the present embodiment, the neural network is a so-called deep neural network which includes one or more hidden layers between an input layer and an output layer. In the neural network, a weighting parameter is defined which represents the connection strength of each of a plurality of neurons included in each hidden layer with the lower layer. The neural network is configured in an aspect in which the sum of values obtained by multiplying each of input values from a plurality of neurons of the upper layer by a weighting parameter defined for each neuron of the upper layer is output to neurons of the lower layer through a threshold function. The wafer table collation unit 43A performs a machine learning, specifically, a deep learning on the neural network, so that the weighting parameter described above may be optimized. As a result, for example, as illustrated in FIG. 10, the wafer table generated by the wafer table generation unit 42A is input as an input signal to the neural network, and the neural network outputs the presence/absence of an abnormality and a factor of the abnormality as an output signal. As a result, the wafer table collation unit 43A may estimate the presence/absence of an abnormality and the factor of the abnormality for the predetermined film formed when the film forming apparatus 10 executes the film forming process.

Meanwhile, in the embodiment above, the film forming apparatus 10 is an example of the semiconductor manufacturing apparatus, the wafer map is an example of a substrate map and substrate information, and the wafer table is an example of a substrate table and substrate information. Further, the group management controller 40 or 40A is an example of an abnormality detecting apparatus.

In the embodiment above, descriptions are made on a case where the group management controller 40 or 40A executes the abnormality detecting method. However, the present disclosure is not limited thereto. For example, the apparatus controller 12, the terminal 60, or a host computer may execute the abnormality detecting method.

According to the present disclosure, a factor of an abnormality in product quality may be automatically estimated.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An abnormality detecting method comprising:
generating substrate information that represents a relationship between an in-plane position of a substrate processed in a semiconductor manufacturing apparatus and a film characteristic; and
determining whether the film characteristic of the processed substrate is abnormal, based on the substrate information generated in the generating, and association information in which substrate information and abnormality factors are associated with each other.

2. The abnormality detecting method according to claim 1, wherein the determining estimates an abnormality factor when determined that the film characteristic of the processed substrate is abnormal.

3. The abnormality detecting method according to claim 2, wherein the determining further includes executing an abnormality recovering process that is predetermined for the abnormality factor estimated in the determining.

4. The abnormality detecting method according to claim 3, wherein the substrate information is generated based on an actual measurement value obtained after the substrate is processed.

5. The abnormality detecting method according to claim 3, wherein the substrate information is generated based on a predicted value that is predicted from a process condition when the substrate is processed.

6. The abnormality detecting method according to claim 5, wherein the substrate information includes a substrate map that represents a distribution of the film characteristic in a plane of the substrate.

7. The abnormality detecting method according to claim 5, wherein the substrate information includes a substrate table that represents a relationship between the in-plane position of the substrate and the film characteristic.

8. The abnormality detecting method according to claim 7, wherein the film characteristic includes any one of a film thickness, a film quality, and particles.

9. The abnormality detecting method according to claim 8, wherein the determining determines whether the film characteristic of the processed substrate is abnormal, through a machine learning.

10. The abnormality detecting method according to claim 1, wherein the substrate information is generated based on an actual measurement value obtained after the substrate is processed.

11. The abnormality detecting method according to claim 1, wherein the substrate information is generated based on a predicted value that is predicted from a process condition when the substrate is processed.

12. The abnormality detecting method according to claim 1, wherein the substrate information includes a substrate map that represents a distribution of the film characteristic in a plane of the substrate.

13. The abnormality detecting method according to claim 1, wherein the substrate information includes a substrate table that represents a relationship between the in-plane position of the substrate and the film characteristic.

14. The abnormality detecting method according to claim 1, wherein the film characteristic includes any one of a film thickness, a film quality, and particles.

15. The abnormality detecting method according to claim 1, wherein the determining determines whether the film characteristic of the processed substrate is abnormal, through a machine learning.

16. An abnormality detecting apparatus comprising:
a memory; and
a processor coupled to the memory and configured to:
generate substrate information that represents a relationship between an in-plane position of a substrate processed in a semiconductor manufacturing apparatus and a film characteristic;
store the substrate information, and association information in which substrate information and abnormality factors are associated with each other to the memory; and
determine whether the film characteristic of the processed substrate is abnormal, based on the substrate information and the association information stored in the memory.
